(19) United States
(12) Patent Application Publication
(10) Pub. No.: US 2024/0274743 A1
(43) Pub. Date: Aug. 15, 2024

(54) SEMICONDUCTOR DEVICE

(71) Applicant: Rohm Co., Ltd., Kyoto-shi (JP)

(72) Inventors: Hiroaki MATSUBARA, Kyoto-shi (JP); Yoshizo OSUMI, Kyoto-shi (JP)

(21) Appl. No.: 18/630,525

(22) Filed: Apr. 9, 2024

Related U.S. Application Data
(63) Continuation of application No. PCT/JP2022/038142, filed on Oct. 13, 2022.

(30) Foreign Application Priority Data
Oct. 20, 2021 (JP) 2021-171573

(51) Int. Cl. H01L 31/16; H01L 33/56; H01L 33/62

(52) U.S. Cl. CPC H01L 31/162; H01L 33/56; H01L 33/62

(57) ABSTRACT

A semiconductor device includes a first die pad, a light-receiving element, a light-emitting element, a first sheet, and a resin part. The first die pad has a first obverse surface facing a first side in a thickness direction. The light-receiving element is mounted on the first obverse surface. The light-emitting element is disposed on the first side in the thickness direction with respect to the light-receiving element. The first sheet has light-passing and insulating properties and is interposed between the light-receiving element and the light-emitting element in the thickness direction. The resin part covers the light-receiving element, the light-emitting element and the first sheet. The first sheet includes a first surface facing the first side in the thickness direction and a second surface facing away from the first surface. At least a portion of the first surface and the second surface includes an uneven portion with irregularities.

### TECHNICAL FIELD

The present disclosure relates to a semiconductor device.

### BACKGROUND ART

A semiconductor device (photocoupler) is conventionally known that transmits signals by a light-receiving element receiving light from a light-emitting element. An example of a conventional photocoupler is disclosed in JP-A-2010-153816. The photocoupler disclosed in JP-A-2010-153816 includes an input-side lead, an output-side lead, a light-emitting element, a light-receiving element, an insulating film, a transparent resin, and a sealing resin. The light-receiving element is mounted on the output-side lead. The light-emitting element is mounted on the input-side lead and disposed to face the light-receiving element. The transparent resin covers the light-emitting element and the light-receiving element, and the sealing resin covers the transparent resin. The insulating film is disposed between the light-receiving element and the light-emitting element and covered with the transparent resin or the sealing resin. By interposing the insulating film between the light-receiving element and the light-emitting element, the dielectric strength between the light-receiving element side and the light-emitting element side is improved. However, if the insulating film separates from the resin covering it, the dielectric strength may decrease.

### BRIEF DESCRIPTION OF THE DRAWINGS

FIG. 1 is a plan view of a semiconductor device according to a first embodiment of the present disclosure.

FIG. 2 is a plan view of the semiconductor device shown in FIG. 1, in which a first sheet and a sealing resin are transparent.

FIG. 3 is a partial enlarged view of FIG. 2.

FIG. 4 is a front view of the semiconductor device shown in FIG. 1.

FIG. 5 is a right side view of the semiconductor device shown in FIG. 1.

FIG. 6 is a sectional view taken along line VI-VI in FIG. 3.

FIG. 7 is a partial enlarged view of FIG. 6.

FIG. 8 is a plan view similar to FIG. 3, showing an arrangement example of openings in the first sheet.

FIG. 9 is a sectional view similar to FIG. 6, showing a semiconductor device according to a first variation of the first embodiment.

FIG. 10 is a sectional view similar to FIG. 6, showing a semiconductor device according to a second variation of the first embodiment.

FIG. 11 is a sectional view similar to FIG. 6, showing a semiconductor device according to a third variation of the first embodiment.

FIG. 12 is a plan view of a semiconductor device according to a second embodiment of the present disclosure.

FIG. 13 is a plan view of the semiconductor device shown in FIG. 12, in which the first sheet and the sealing resin are transparent.

FIG. 14 is a partial enlarged view of FIG. 13.

FIG. 15 is a front view of the semiconductor device shown in FIG. 12.

FIG. 16 is a right side view of the semiconductor device shown in FIG. 12.

FIG. 17 is a sectional view taken along line XVII-XVII in FIG. 14.

### DETAILED DESCRIPTION OF EMBODIMENTS

The following describes preferred embodiments of the present disclosure in detail with reference to the drawings. In the present disclosure, the terms such as “first”, “second”, and “third” are used merely as labels and are not intended to impose ordinal requirements on the items to which these terms refer.

In the description of the present disclosure, the expression “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expression “An object A is disposed in an object B”, and “An object A is disposed on an object B” imply the situation where, unless otherwise specifically noted, “the object A is disposed directly in or on the object B”, and “the object A is disposed in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a part of the object B”.

### First Embodiment

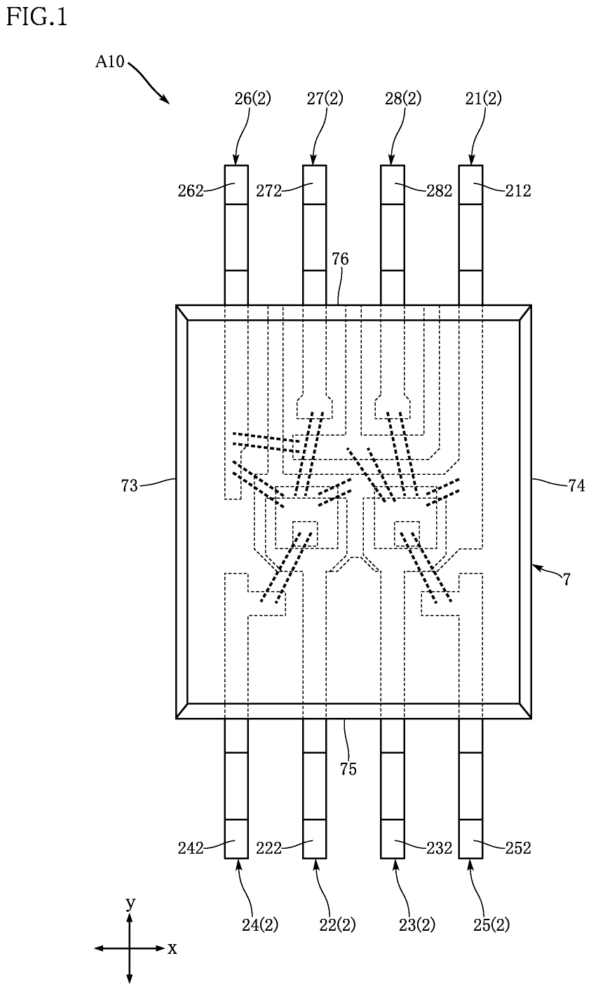

A semiconductor device A10 according to a first embodiment of the present disclosure will be described based on FIGS. 1 to 8. The semiconductor device A10 includes light-receiving elements 11, light-emitting elements 12, a conductive support 2, a plurality of wires 4, a first sheet 5, a transparent resin 6, and a sealing resin 7.

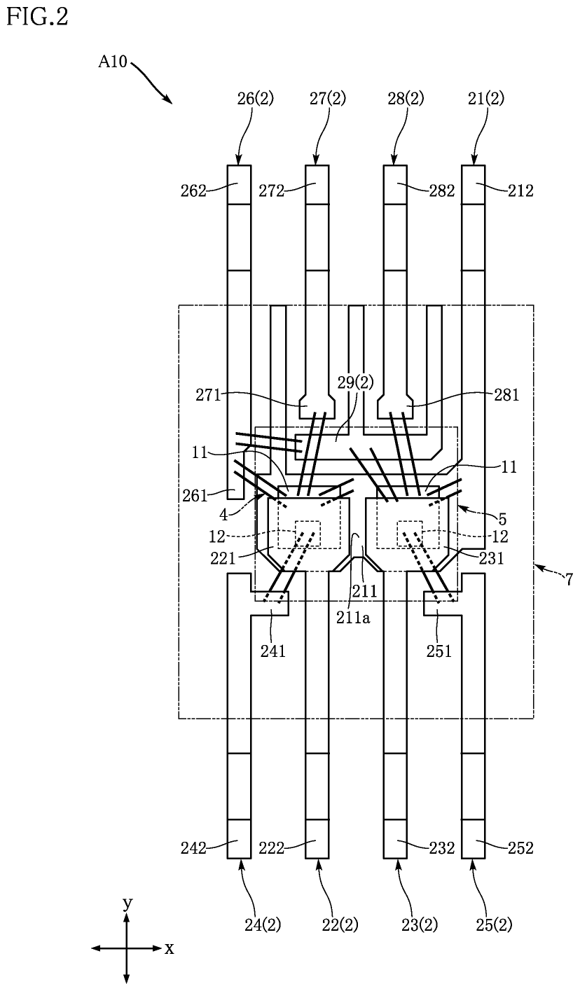

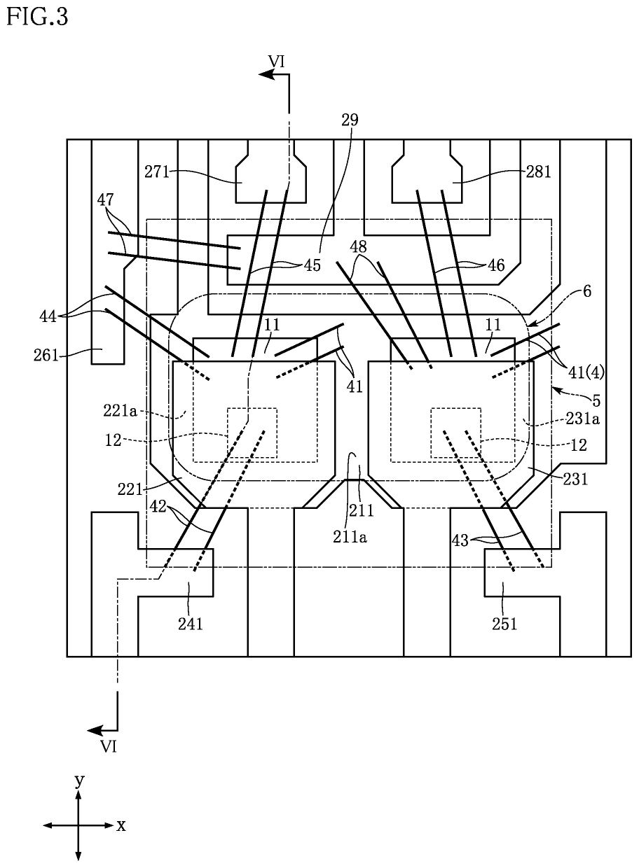

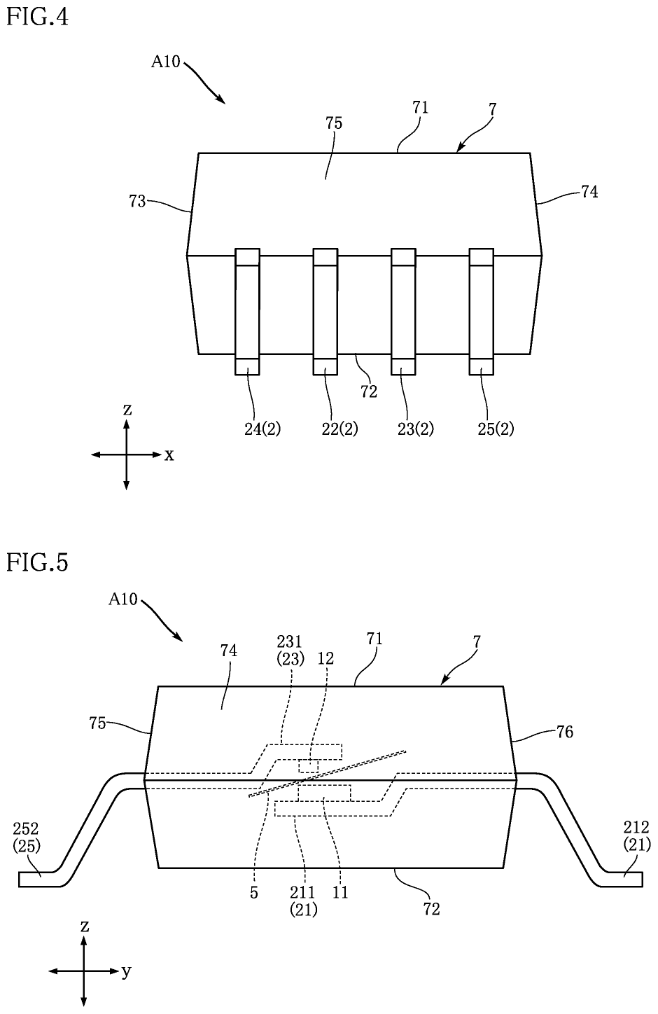

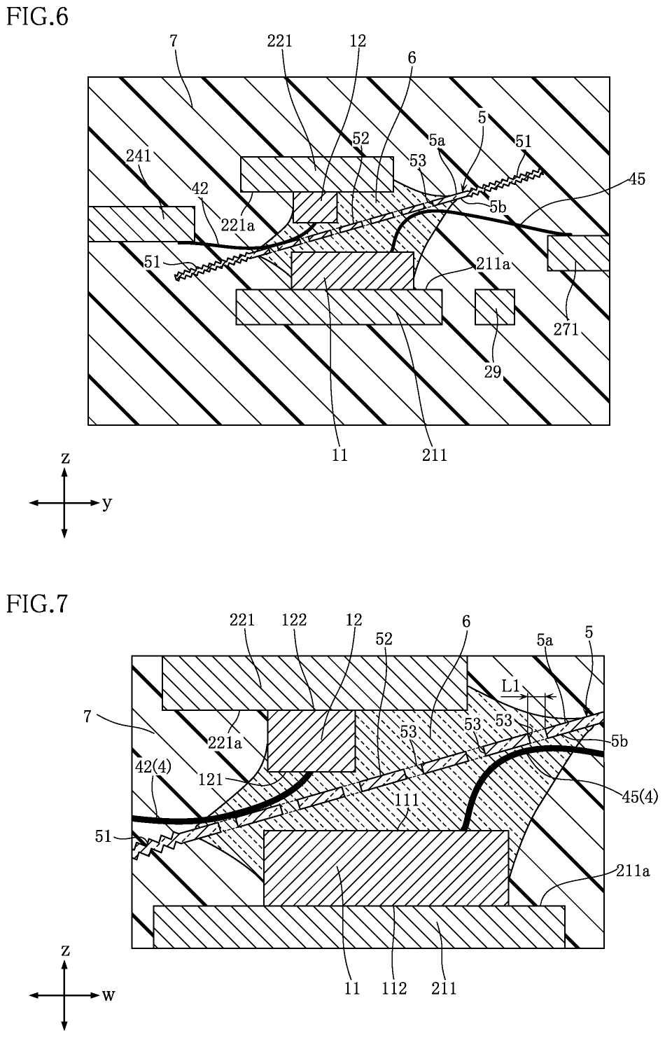

FIG. 1 is a plan view of the semiconductor device A10. FIG. 2 is a plan view of the semiconductor device A10. For the convenience of understanding, in FIG. 2, the first sheet 5 and the sealing resin 7 are transparent, and the outlines of these are indicated by imaginary lines (dash-double dot lines). Additionally, the transparent resin 6 is omitted in FIG. 2. FIG. 3 is a partial enlarged view of FIG. 2. FIG. 4 is a front view of the semiconductor device A10. FIG. 5 is a right side view of the semiconductor device A10. FIG. 6 is a sectional view taken along line VI-VI in FIG. 3. FIG. 7 is a partial enlarged view of FIG. 6. The semiconductor device A10 of the present embodiment includes a plurality of light-receiving elements 11 (two in the illustrated example) and a plurality of light-emitting elements 12 (two in the illustrated example).

The semiconductor device A10 shown in these figures is a device to be surface-mounted on circuit boards of various devices. The applications and functions of the semiconductor device A10 are not limited. The package type of the semiconductor device A10 is the SOP (Small Outline Package). The package type of the semiconductor device A10 is not limited to the SOP. The portion of the semiconductor device A10 that is covered with the sealing resin 7 has a rectangular shape as viewed in the thickness direction. In the description of the semiconductor device A10, the thickness direction of the semiconductor device A10 is called the “thickness direction z”. A direction orthogonal to the thickness direction z is called the “direction x”. The direction orthogonal to both the thickness direction z and the direction x is called the “direction y”. The dimensions of the semiconductor device A10 are not particularly limited.

The conductive support 2 is an electrically conductive member that forms conduction paths between the light-receiving and the light-emitting elements 11 and 12 and the circuit board on which the semiconductor device A10 is mounted. The conductive support 2 is a portion of a lead frame used for manufacturing the semiconductor device A10. The thickness of the conductive support 2 is not particularly limited but may be about 200 μm, for example. The conductive support member 2 is preferably made of Cu or Ni, an alloy of these, or a 42 alloy, for example. The conductive support 2 includes leads 21 to 29. The leads 21 to 29 are spaced apart from each other.

The lead 21 supports the light-receiving elements 11 and is electrically connected to the light-receiving elements 11. The lead 21 includes a first die pad 211 and a terminal portion 212.

As shown in FIG. 2, the first die pad 211 is disposed at the center (or approximately the center) of the semiconductor device A10 in the direction x and the direction y. As shown in FIGS. 2 and 3, the first die pad 211 carries the two light-receiving elements 11. The first die pad 211 has a rectangular shape relatively long along the direction x as viewed in the thickness direction z. The first die pad 211 is electrically connected to each light-receiving element 11 via wires 4 (wires 41 described later). The first die pad 211 is covered with the transparent resin 6 and the sealing resin 7.

As shown in FIGS. 3, 6 and 7, the first die pad 211 has a first obverse surface 211a. The first obverse surface 211a faces a first side in the thickness direction z. The first obverse surface 211a is flat (or generally flat). The light-receiving element 11 is bonded to the first obverse surface 211a. As shown in FIGS. 2 and 3, the two light-receiving elements 11 are spaced apart from each other in the direction x.

As shown in FIG. 2, the terminal portion 212 is connected to the first die pad 211 on a first side in the direction y (the upper side in FIG. 2) and extends toward the first side in the direction y to be partially exposed from the sealing resin 7. The terminal portion 212 is electrically connected to each light-receiving element 11 via the first die pad 211 and wires 41. As shown in FIG. 5, the portion of the terminal portion 212 that is exposed from the sealing resin 7 is bent into a hook shape as viewed in the direction x. The shape of the lead 21 is not limited to the above.

The lead 22 supports a light-emitting element 12 and is electrically connected to the light-emitting element 12. The lead 22 includes a second die pad 221 and a terminal portion 222.

As shown in FIG. 2, the second die pad 221 is disposed at a position offset toward a second side in the direction x at the center (or approximately the center) of the semiconductor device A10 in the direction y. As shown in FIGS. 2, 3 and 6, the second die pad 221 is spaced apart from the first die pad 211 toward the first side in the thickness direction z and overlaps with the first die pad 211 as viewed in the thickness direction z. The second die pad 221 carries one light-emitting element 12. The second die pad 221 is rectangular (or generally rectangular) as viewed in the thickness direction z. As shown in FIGS. 2, 3 and 6, the second die pad 221 is covered with the transparent resin 6 and the sealing resin 7.

As shown in FIGS. 3, 6 and 7, the second die pad 221 has a second obverse surface 221a. The second obverse surface 221a faces a second side in the thickness direction z and faces the first obverse surface 211a of the first die pad 211. The second obverse surface 221a is flat (or generally flat). One of the two light-emitting elements 12 is bonded to the second obverse surface 221a.

As shown in FIG. 2, the terminal portion 222 is connected to the second die pad 221 on a second side in the direction y (the lower side in FIG. 2) and extends toward the second side in the direction y to be partially exposed from the sealing resin 7. The terminal portion 222 is electrically connected to the light-emitting element 12 via the second die pad 221. The portion of the terminal portion 222 that is exposed from the sealing resin 7 is bent into a hook shape as viewed in the direction x. The shape of the lead 22 is not limited to the above.

The lead 23 supports a light-emitting element 12 and is electrically connected to the light-emitting element 12. The lead 23 includes a second die pad 231 and a terminal portion 232. The lead 23 has the same configuration as the lead 22.

As shown in FIG. 2, the second die pad 231 is disposed at a position offset toward a first side in the direction x at the center (or approximately the center) of the semiconductor device A10 in the direction y. The second die pad 231 is located on the first side in the direction x with respect to the second die pad 221. As with the second die pad 221, the second die pad 231 is spaced apart from the first die pad 211 toward the first side in the thickness direction z and overlaps with the first die pad 211 as viewed in the thickness direction z. The second die pad 231 carries one light-emitting element 12. The second die pad 231 is rectangular (or generally rectangular) as viewed in the thickness direction z. As with the second die pad 221, the second die pad 231 is covered with the transparent resin 6 and the sealing resin 7.

As shown in FIG. 3, the second die pad 231 has a second obverse surface 231a. As with the second obverse surface 221a, the second obverse surface 231a faces the second side in the thickness direction z, faces the first obverse surface 211a of the first die pad 211, and is flat (or generally flat). The other one of the two light-emitting elements 12 is bonded to the second obverse surface 231a.

As shown in FIG. 2, the terminal portion 232 is connected to the second die pad 231 on the second side in the direction y (the lower side in FIG. 2) and extends toward the second side in the direction y to be partially exposed from the sealing resin 7. The terminal portion 232 is electrically connected to the light-emitting element 12 via the second die pad 231. The portion of the terminal portion 232 that is exposed from the sealing resin 7 is bent into a hook shape as viewed in the direction x. The shape of the lead 23 is not limited to the above.

The lead 24 is electrically connected to a light-emitting element 12. The lead 24 includes a pad portion 241 and a terminal portion 242.

As shown in FIGS. 2 and 3, the pad portion 241 is disposed on the second side in the direction x and the second side in the direction y with respect to the second die pad 221. The pad portion 241 is electrically connected to the light-emitting element 12 (the light-emitting element 12 mounted on the second obverse surface 221a of the second die pad 221) via the wires 4 (wires 42 described later). The pad portion 241 is covered with the sealing resin 7. The pad portion 241 is rectangular as viewed in the thickness direction z. The wires 42 are bonded to the surface of the pad portion 241 that faces the second side in the thickness direction z.

As shown in FIG. 2, the terminal portion 242 is connected to the pad portion 241 and extends toward the second side in the direction y (the lower side in FIG. 2) to be partially exposed from the sealing resin 7. The terminal portion 242 is electrically connected to a light-emitting element 12 via the pad portion 241 and the wires 42. The portion of the terminal portion 242 that is exposed from the sealing resin 7 is bent into a hook shape as viewed in the direction x. The shape of the lead 24 is not limited to the above.

The lead 25 is electrically connected to a light-emitting element 12. The lead 25 includes a pad portion 251 and a terminal portion 252. The lead 25 has the same configuration as the lead 24.

As shown in FIGS. 2 and 3, the pad portion 251 is disposed on the first side in the direction x and the second side in the direction y with respect to the second die pad 231. The pad portion 251 is electrically connected to the light-emitting element 12 (the light-emitting element 12 mounted on the second obverse surface 231a of the second die pad 231) via the wires 4 (wires 43 described later). The pad portion 251 is covered with the sealing resin 7. The pad portion 251 is rectangular as viewed in the thickness direction z. The wires 43 are bonded to the surface of the pad portion 251 that faces the second side in the thickness direction z.

As shown in FIG. 2, the terminal portion 252 is connected to the pad portion 251 and extends toward the second side in the direction y (the lower side in FIG. 2) to be partially exposed from the sealing resin 7. The terminal portion 252 is electrically connected to the light-emitting element 12 via the pad portion 251 and the wires 43. As shown in FIG. 5, the portion of the terminal portion 252 that is exposed from the sealing resin 7 is bent into a hook shape as viewed in the direction x. The shape of the lead 25 is not limited to the above.

As shown in FIG. 1, the terminal portions 242, 222, 232 and 252 protrude from the surface of the sealing resin 7 on the second side in the direction y (resin side surface 75 described later) and are arranged at equal intervals in this order from the second side toward the first side in the direction x.

The lead 26 is electrically connected to a light-receiving element 11. The lead 26 includes a pad portion 261 and a terminal portion 262.

As shown in FIGS. 2 and 3, the pad portion 261 is disposed on the second side in the direction x and the first side in the direction y with respect to the first die pad 211. The pad portion 261 is electrically connected to the light-receiving element 11 (the light-receiving element disposed on the second side in the direction x) via the wires 4 (wires 44 described later). The pad portion 261 is covered with the sealing resin 7. The pad portion 261 is rectangular (or generally rectangular) as viewed in the thickness direction z. The wires 44 are bonded to the surface of the pad portion 261 that faces the first side in the thickness direction z.

As shown in FIG. 2, the terminal portion 262 is connected to the pad portion 261 on the first side in the direction y (the upper side in FIG. 2) and extends toward the first side in the direction y to be partially exposed from the sealing resin 7. The terminal portion 262 is electrically connected to the light-receiving element 11 via the pad portion 261 and the wires 44. The portion of the terminal portion 262 that is exposed from the sealing resin 7 is bent into a hook shape as viewed in the direction x. The shape of the lead 26 is not limited to the above.

The lead 27 is electrically connected to a light-receiving element 11. The lead 27 includes a pad portion 271 and a terminal portion 272.

As shown in FIG. 2, the pad portion 271 is disposed on the first side in the direction y with respect to the first die pad 211. The pad portion 271 is electrically connected to the light-receiving element 11 (the light-receiving element disposed on the second side in the direction x) via the wires 4 (wires 45 described later). The pad portion 271 is covered with the sealing resin 7. The pad portion 271 is rectangular (or generally rectangular) as viewed in the thickness direction z. The wires 45 are bonded to the surface of the pad portion 271 that faces the first side in the thickness direction z.

As shown in FIG. 2, the terminal portion 272 is connected to the pad portion 271 on the first side in the direction y (the upper side in FIG. 2) and extends toward the first side in the direction y to be partially exposed from the sealing resin 7. The terminal portion 272 is electrically connected to the light-receiving element 11 via the pad portion 271 and the wires 45. The portion of the terminal portion 272 that is exposed from the sealing resin 7 is bent into a hook shape as viewed in the direction x. The shape of the lead 27 is not limited to the above.

The lead 28 is electrically connected to a light-receiving element 11. The lead 28 includes a pad portion 281 and a terminal portion 282. The lead 28 has the same configuration as the lead 27.

As shown in FIG. 2, the pad portion 281 is disposed on the first side in the direction y with respect to the first die pad 211. The pad portion 271 is electrically connected to the light-receiving element 11 (the light-receiving element 11 disposed on the first side in the direction x) via the wires 4 (wires 46 described later). The pad portion 281 is covered with the sealing resin 7. The pad portion 281 is rectangular (or generally rectangular) as viewed in the thickness direction z. The wires 46 are bonded to the surface of the pad portion 281 that faces the first side in the thickness direction z.

As shown in FIG. 2, the terminal portion 282 is connected to the pad portion 281 on the first side in the direction y (the upper side in FIG. 2) and extends toward the first side in the direction y to be partially exposed from the sealing resin 7. The terminal portion 282 is electrically connected to the light-receiving element 11 via the pad portion 281 and the wires 46. The portion of the terminal portion 282 that is exposed from the sealing resin 7 is bent into a hook shape as viewed in the direction x. The shape of the lead 28 is not limited to the above.

As shown in FIG. 1, the terminal portions 262, 272, 282 and 212 protrude from the surface of the sealing resin 7 on the first side in the direction y (resin side surface 76 described later) and are arranged at equal intervals in this order from the second side toward the first side in the direction x.

As shown in FIGS. 2 and 3, the lead 29 is disposed on the first side in the direction y with respect to the first die pad 211. The lead 29 211 has a rectangular shape relatively long along the direction x as viewed in the thickness direction z. The lead 29 is covered with the sealing resin 7. The wires 4 (wires 47 and wires 48 described later) are bonded to the surface of the lead 29 that faces the first side in the thickness direction z.

The light-emitting elements 12 are LED chips, for example, and configured to emit light of a predetermined wavelength. The constituent material of the light-emitting elements 12 includes a semiconductor material. The light-emitting elements 12 have the shape of a rectangular plate as viewed in the thickness direction z. As shown in FIG. 7, the light-emitting element 12 has an obverse surface 121 and a reverse surface 122. The obverse surface 121 and the reverse surface 122 face away from each other in the thickness direction z. The obverse surface 121 faces the second side in the thickness direction z. The reverse surface 122 faces the first side in the thickness direction z. The light-emitting element 12 is provided with a cathode electrode (not shown) disposed on the obverse surface 121 and an anode electrode (not shown) disposed on the reverse surface 122.

The one of the light-emitting elements 12 shown in FIG. 7 and the other light-emitting element 12 are bonded to the second obverse surfaces 221a and 231a of the second die pads 221 and 231 via a bonding material, not shown. The bonding material is an electrically conductive bonding material and may be solder, for example, though not particularly limited. The light-emitting elements 12 are bonded at their reverse surfaces 122 to the second obverse surfaces 221a and 231a of the second die pads 221 and 231 with a bonding material. The anode electrodes of the light-emitting elements 12 are electrically connected to the second die pads 221 and 231 via a bonding material. Thus, the terminal portions 222 and 232 of the leads 22 and 23 electrically conduct to the anode electrodes of the light-emitting elements 12 to function as anode terminals. As shown in FIG. 3, the cathode electrodes of the light-emitting elements 12 are electrically connected to the pad portions 241 and 251 of the leads 24 and 25 via the wires 42 and 43. Thus, the terminal portions 242 and 252 of the leads 24 and 25 electrically conduct to the cathode electrodes of the light-emitting elements 12 to function as cathode terminals.

The light-emitting elements 12 are covered with the transparent resin 6 at portions including at least the obverse surfaces 121. Each light-emitting element 12 emits light in response to a current that flows when a voltage is applied between the anode electrode and the cathode electrode. The light emitted from the light-emitting element 12 travels through the transparent resin 6 to reach the light-receiving element 11.

The light-receiving elements 11 receive the light emitted from the light-emitting elements 12. The constituent material of the light-receiving elements 11 includes a semiconductor material. The light-receiving elements 11 have the shape of a rectangular plate as viewed in the thickness direction z. As shown in FIG. 7, the light-receiving element 11 has an obverse surface 111 and a reverse surface 112. The obverse surface 111 and the reverse surface 112 face away from each other in the thickness direction z. The obverse surface 111 faces the first side in the thickness direction z. The obverse surface 111 faces the obverse surface 121 of the light-emitting element 12. The reverse surface 112 faces the second side in the thickness direction z.

The one of the light-receiving elements 11 shown in FIG. 7 and the other light-receiving elements 11 are bonded to the first obverse surface 211a of the first die pad 211 via a bonding material, not shown. The bonding material is not particularly limited but may be an insulating bonding material, for example. The light-receiving elements 11 are bonded at their reverse surfaces 112 to the first obverse surface 211a of the first die pad 211 with a bonding material.

Each light-receiving element 11 has a light-receiving section and a circuit forming section (both not shown) disposed on the obverse surface 111. The light-receiving section is offset on the obverse surface 111 toward the second side in the direction y. The light-receiving section has a photodiode, for example, and generates an electromotive force in accordance with the amount of light received. The obverse surface 111 of the light-receiving element 11 is entirely covered with the transparent resin 6. Thus, the light-receiving section can properly receive the light emitted from the light-emitting element 12 through the transparent resin 6.

The circuit forming section is offset on the obverse surface 111 toward the first side in the direction y. A circuit including a transistor and the like is formed in the circuit forming section. The circuit forming section amplifies the electromotive force generated by the light-receiving section receiving light, and outputs it. The circuit forming section has a plurality of electrodes disposed therein. As shown in FIG. 3, the electrodes are electrically connected to the leads 21, 26, and 27, or the leads 21, 26, and 28 via wires 4. Specifically, the power supply electrodes of the light-receiving elements 11 are electrically connected to the pad portion 261 of the lead 26 via the wires 44 or the wires 47 and 48. Thus, the terminal portion 262 of the lead 26 electrically conducts to the power supply electrodes of the light-receiving elements 11 to function as a power supply terminal. The ground electrodes of the light-receiving elements 11 are electrically connected to the first die pad 211 via the wires 41. Thus, the terminal portion 212 of the lead 21 electrically conducts to the ground electrodes of the light-receiving elements 11 to function as a ground terminal. The output electrodes of the light-receiving elements 11 are electrically connected to the pad portions 271 and 281 of the leads 27 and 28 via the wires 45 and 46. Thus, the terminal portions 272 and 282 of the leads 27 and 28 electrically conduct to the output electrodes of the light-receiving elements 11 to function as output terminals.

When a voltage is applied between the terminal portion 222 or 232 and the terminal portion 242 or 252, a voltage is applied between the anode electrode and the cathode electrode of the light-emitting element 12, causing a current to flow. As a result, the light-emitting element 12 emits light. The light-receiving section of the light-receiving element 11, when receives light, generates an electromotive force corresponding to the amount of light received. The electromotive force is amplified in the circuit forming section by the power supplied between the terminal portion 262 and the terminal portion 212 and then outputted from the terminal portion 272 or 282. In this way, the semiconductor device A10 is capable of transmitting signals from the input side (terminal portion 222 or 232 and terminal portion 242 or 252) to the output side (terminal portions 272 or 282) while the input side and the output side are electrically insulated from each other.

As shown in FIGS. 2 and 3, the wires 4 are conductive members that form, with the conductive support 2, conduction paths between the light-emitting and the light-receiving elements 12 and 11 and a circuit board. The constituent material of the wires 4 is a metal containing Au, Cu, or Al, for example. The wires 4 include wires 41 to 48.

The wires 41 form conduction paths between the light-receiving elements 11 and the lead 21. The wires 41 are bonded to the ground electrodes of the light-receiving elements 11 and the first die pad 211. The number of wires 41 is not limited. The wires 42 are bonded to the cathode electrode of one of the light-emitting elements 12 and the pad portion 241 of the lead 24. The number of wires 42 is not limited. The wires 43 are bonded to the cathode electrode of the other light-emitting element 12 and the pad portion 251 of the lead 25. The number of wires 43 is not limited. The wires 44 form a conduction path between one of the light-receiving elements 11 and the lead 26. The wires 44 are bonded to the power supply electrode of the light-receiving element 11 and the pad portion 261 of the lead 26. The number of wires 44 is not limited. The wires 45 form a conduction path between one of the light-receiving elements 11 and the lead 27. The wires 45 are bonded to the output electrode of the light-receiving element 11 and the pad portion 271 of the lead 27. The number of wires 45 is not limited. The wires 46 form a conduction path between the other light-receiving element 11 and the lead 28. The wires 46 are bonded to the output electrode of the light-receiving element 11 and the pad portion 281 of the lead 28. The number of wires 46 is not limited. The wires 47 form a conduction path between the lead 29 and the lead 26. The wires 47 are bonded to the lead 29 and the pad portion 261 of the lead 26. The number of wires 47 is not limited. The wires 48 form a conduction path between the above-described other light-receiving element 11 and the lead 26. The wires 48 are bonded to the power supply electrode of the light-receiving element 11 and the lead 29. The number of wires 48 is not limited.

As shown in FIG. 6, the first sheet 5 is interposed between the light-receiving element 11 and the light-emitting element 12 in the thickness direction z. The first sheet 5 is a plate-like member having light-passing properties and electrical insulation properties. The constituent material of the first sheet 5 is not particularly limited as long as it is an insulating material that transmits light. In an example, the first sheet 5 may be entirely made of a transparent material.

As shown in FIGS. 2 and 3, the first sheet 5 is rectangular as viewed in the thickness direction z. The first sheet 5 overlaps with all of the light-receiving elements 11, the light-emitting elements 12, the first die pad 211 and the second die pads 221 and 231 as viewed in the thickness direction z. The light emitted from the light-emitting elements 12 passes through the first sheet 5 located between the light-emitting elements 12 and the light-receiving elements 11 opposing thereto. The shape of the first sheet 5 is not limited to the above.

As shown in FIGS. 6 and 7, the first sheet 5 has a first surface 5a and a second surface 5b. The first surface 5a faces the first side in the thickness direction z. The second surface 5b faces away from the first surface 5a and faces the second side in the thickness direction z. As shown in FIG. 6, the first sheet 5 in the present embodiment is inclined to extend toward the first side in the thickness direction z (upper side in the figure) as proceeding from the second side (left side in the figure) toward the first side (right side in the figure) in the direction y, as viewed in the direction x. By disposing the first sheet 5 in such an inclined orientation, an excessive stress on the wires 4 around the first sheet 5 (e.g., wires 42 and 45 in FIG. 6) is prevented from occurring due to contact with the first sheet 5.

In the present embodiment, the first sheet 5 has an uneven portion 51, a flat portion 52, and a plurality of openings 53. In the present embodiment, the uneven portion 51 is a portion where at least a portion of the first surface 5a and the second surface 5b is made irregular. The shape, arrangement, and height of the irregularities of the uneven portion 51 are not limited.

In the present embodiment, the uneven portion 51 is provided in a region close to the outer periphery of the first sheet 5. More specifically, the uneven portion 51 is provided on both the first surface 5a and the second surface 5b in a frame-like region close to the outer periphery of the first sheet 5. Preferably, the uneven portion 51 has a surface roughness greater than a predetermined value. The uneven portion 51 has a surface area that is, for example, 1.5 times or greater than the surface area when no irregularities are formed. The upper limit of the surface area of the uneven portion 51 is not particularly limited. As an example, to prevent an inconvenience such as the thickness of the first sheet 5 becoming extremely uneven, it is preferable that the surface area of the uneven portion 51 is not greater than 2.5 times the surface area when no irregularities are formed.

The flat portion 52 is a portion that is flatter than the uneven portion 51. The flat portion 52 is provided in an inner region surrounded by the uneven portion 51.

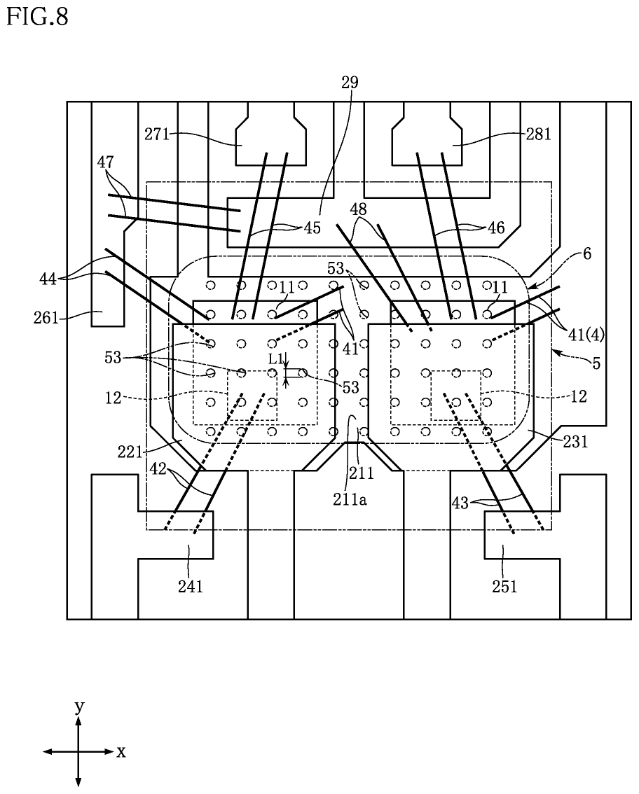

The openings 53 are through-holes penetrating from the first surface 5a to the second surface 5b. The shape and arrangement of the openings 53 are not limited. FIG. 8 is a plan view showing an example of arrangement of the openings 53. The illustrated example shows the case where each opening 53 has a circular shape. The openings 53 are distributed in the in-plane direction of the first sheet 5. In the present embodiment, the openings 53 are provided in the flat portion 52. The size of each opening 53 is not limited. As an example of the size of each opening 53, as shown in FIG. 7, the dimension L1 of each opening 53 in the direction w in which the wires 4 extend as viewed in the thickness direction z is in the range of 0.5 to 2 times the diameter of the wires 4. Because the openings 53 are circular in the present embodiment, the diameter of the openings 53, for example, is about 0.5 to 2 times the diameter of the wires 4.

As shown in FIGS. 3, 6 and 7, the transparent resin 6 covers portions of the conductive support 2, portions of the light-receiving elements 11 (at least the obverse surfaces 111), portions of the light-emitting elements 12 (at least the obverse surfaces 121), portions of the wires 4, and portions of the first sheet 5. The transparent resin 6 has an electrically insulating property. The transparent resin 6 includes a transparent epoxy resin, for example. The constituent material of the transparent resin 6 is not limited as long as it allows light to pass through.

The transparent resin 6 is formed, for example, by potting the material of the transparent resin 6 between the light-receiving elements 11 and the first sheet 5 (the second surface 5b) and between the light-emitting elements 12 and the first sheet 5 (the first surface 5a). The method for forming the transparent resin 6 is not limited to the above. In the present embodiment, the transparent resin 6 is in contact with only the flat portion 52 of the first sheet 5 (the first surface 5a and the second surface 5b of the flat portion 52) and covers most of the flat portion 52. Also, the transparent resin 6 is loaded into the openings 53 of the first sheet 5. The transparent resin 6 described above is an example of “resin part” of the present disclosure.

The sealing resin 7 covers portions of the conductive support 2, the light-receiving elements 11, the light-emitting elements 12, portions of the wires 4, portions of the first sheet 5, and the transparent resin 6. More specifically, the sealing resin 7 is in contact with the entirety of the uneven portion 51 of the first sheet 5 and portions of the flat portion 52. The sealing resin 7 has an electrically insulating property. The sealing resin 7 includes a black epoxy resin, for example. The constituent material of the sealing resin 7 is not limited. The sealing resin 7 is formed by transfer molding using a mold, for example. The sealing resin 7 is rectangular as viewed in the thickness direction z.

The sealing resin 7 includes a resin top surface 71, a resin bottom surface 72, and resin side surfaces 73 to 76. The resin top surface 71 and the resin bottom surface 72 face away from each other in the thickness direction z. The resin top surface 71 faces the first side in the thickness direction z, and the resin bottom surface 72 faces the second side in the thickness direction z. The resin top surface 71 and the resin bottom surface 72 are flat (or generally flat).

Each of the resin side surfaces 73 to 76 is connected to the resin top surface 71 and the resin bottom surface 72 and located between the resin top surface 71 and the resin bottom surface 72 in the thickness direction z. The resin side surface 73 and the resin side surface 74 face away from each other in the direction x. The resin side surface 73 faces the second side in the direction x, and the resin side surface 74 faces the first side in the direction x. The resin side surface 75 and the resin side surface 76 face away from each other in the direction y. The resin side surface 75 faces the second side in the direction y, and the resin side surface 76 faces the first side in the direction y. As shown in FIG. 1, each of the terminal portions 242, 222, 232 and 252 partially protrudes from the resin side surface 75. Each of the terminal portions 262, 272, 282 and 212 partially protrudes from the resin side surface 76. The conductive support 2 is not exposed from the resin side surface 73 and the resin side surface 74.

As shown in FIGS. 4 and 5, the resin side surfaces 73 to 76 include surface portions connected to the resin top surface 71 and inclined to approach each other as proceeding toward the resin top surface 71. Accordingly, the portion of the sealing resin 7 that is surrounded by such inclined surface portions connected to the resin top surface 71 is tapered, with the cross-sectional area in the xy-plane decreasing toward the resin top surface 71. Also, the resin side surfaces 73 to 76 include surface portions connected to the resin bottom surface 72 and inclined to approach each other as proceeding toward the resin bottom surface 72. Accordingly, the portion of the sealing resin 7 that is surrounded by such inclined surfaces portions connected to the resin bottom surface 72 is tapered, with the cross-sectional area in the xy-plane decreasing toward the resin bottom surface 72. The shape of the sealing resin 7 shown in FIGS. 1, 4 and 5 is one example. The shape of the sealing resin 7 is not limited to the illustrated shape. The sealing resin 7 described above is an example of “resin part” of the present disclosure.

The effects of the present embodiment will be described.

The semiconductor device A10 includes the light-receiving elements 11, the light-emitting elements 12, the first sheet 5, the transparent resin 6, and the sealing resin 7. The light-receiving elements 11 are mounted on the first obverse surface 211a of the first die pad 211 that faces the first side in the thickness direction z. The light-emitting elements 12 are disposed on the first side in the thickness direction z with respect to the light-receiving elements 11. The first sheet 5 has the first surface 5a and the second surface 5b facing the first side and the second side, respectively, in the thickness direction z. The first sheet 5 allows light to pass through and has insulating properties, and is interposed between the light-receiving elements 11 and the light-emitting elements 12 in the thickness direction z. The first sheet 5 is covered with the transparent resin 6 and the sealing resin 7. At least a portion of the first surface 5a and the second surface 5b of the first sheet 5 includes the uneven portion 51 with irregularities.

With such a configuration, the uneven portion 51 of the first sheet 5, which comes into contact with the transparent resin 6 or the sealing resin 7, has improved adhesion to the transparent resin 6 or the sealing resin 7. This prevents the first sheet 5 from separating from the transparent resin 6 or the sealing resin 7 covering it and suppresses a decrease in the dielectric strength.

The light-emitting elements 12 are mounted on the second die pads 221 and 231 spaced apart from the first die pad 211 toward the first side in the thickness direction z. The light-emitting elements 12 are mounted on the second obverse surface 221a and 231a of the second die pads 221 and 231 that face the second side in the thickness direction z. The light-emitting elements 12 overlap with the light-receiving elements 11 as viewed in the thickness direction z. The first sheet 5 is disposed between the light-receiving elements 11 and the light-emitting elements 12 that face each other in the thickness direction z. The transparent resin 6 covers a portion of each of the light-receiving elements 11 and light-emitting elements 12, and a portion of the first sheet 5. The sealing resin 7 covers the transparent resin 6 and a portion of the first sheet 5. The uneven portion 51 of the first sheet 5 is provided in a region close to the outer periphery of the first sheet 5 and held in contact with the sealing resin 7. With such a configuration, the first sheet 5, which is disposed between the light-receiving elements 11 and the light-emitting elements 12 facing each other, is appropriately prevented from separating from the sealing resin 7 because of the uneven portion 51 being held in contact with the sealing resin 7, whereby a decrease in the dielectric strength is suppressed.

The first surface 5a and the second surface 5b of the first sheet 5 has the flat portion 52 that is flatter than the uneven portion 51. The transparent resin 6 is in contact with only the flat portion 52 (the first surface 5a and the second surface 5b in the flat portion 52 located inward of the uneven portion 51), out of the first surface 5a and the second surface 5b. With such a configuration, the light emitted from the light-emitting elements 12 passes through the flat portion 52 of the first sheet 5. Thus, the light passing through the first sheet 5 is prevented from scattering, whereby the light from the light-emitting elements 12 can be properly received by the light-receiving elements 11.

The first sheet 5 is formed with the openings 53. Each opening 53 penetrates from the first surface 5a to the second surface 5b. The openings 53 are provided in the flat portion 52 and filled with the transparent resin 6 (resin part). Such a configuration improves the adhesion between the portion of the first sheet 5 that is formed with the openings 53 and the transparent resin 6 (resin part). Thus, the portion of the first sheet 5 that is formed with the openings 53 is prevented from separating from the transparent resin 6, whereby a decrease in the dielectric strength is further suppressed.

The wires 4 are bonded to the light-receiving elements 11 and the light-emitting elements 12. The dimension L1 of each opening 53 in the direction w in which the wires 4 extend as viewed in the thickness direction z is in the range of 0.5 to 2 times the diameter of the wires 4. With such a configuration, a wire 4 bonded to a light-receiving element 11 and a wire 4 bonded to a light-emitting element 12 will not come into contact with each other through an opening 53, whereby the dielectric strength between the light-receiving element 11 side and the light-emitting element 12 side is appropriately maintained.

### First Variation of the First Embodiment

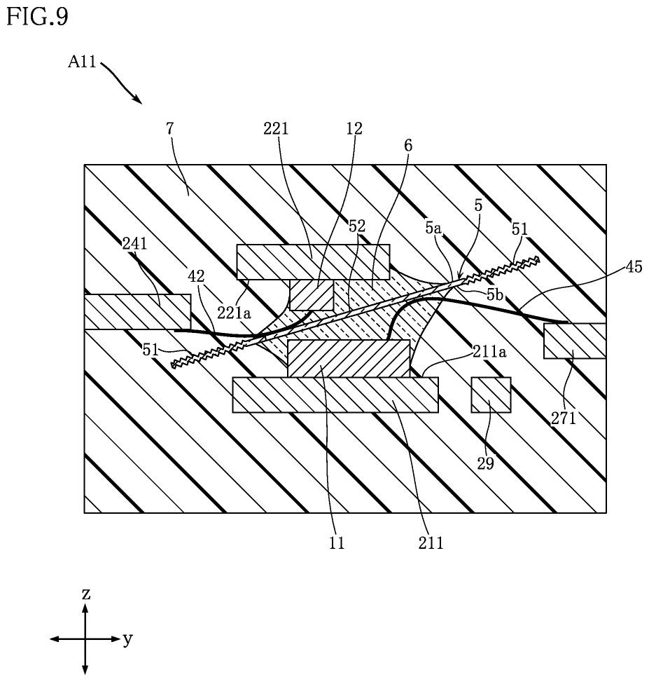

FIG. 9 shows a semiconductor device according to a first variation of the first embodiment. FIG. 9 is a sectional view similar to FIG. 6 shown in the above-described embodiment. In FIG. 9 and subsequent drawings, the elements that are identical or similar to those of the semiconductor device A10 of the above-described embodiment are denoted by the same reference signs as those of the above-described embodiment, and the descriptions thereof are omitted as appropriate.

The semiconductor device A11 of the present variation differs from the above-described embodiment in configuration of the first sheet 5. In the present variation, the first sheet 5 is not formed with openings 53. The first sheet 5 is covered with the transparent resin 6 and the sealing resin 7. At least a portion of the first surface 5a and the second surface 5b of the first sheet 5 includes the uneven portion 51 with irregularities.

With such a configuration, the uneven portion 51 of the first sheet 5, which comes into contact with the transparent resin 6 or the sealing resin 7, has improved adhesion to the transparent resin 6 or the sealing resin 7. This prevents the first sheet 5 from separating from the transparent resin 6 or the sealing resin 7 covering it and suppresses a decrease in the dielectric strength. Additionally, the same effect as the semiconductor device A10 of the above-described embodiment is also provided owing to the configuration in common with the above-described embodiment.

### Second Variation of the First Embodiment

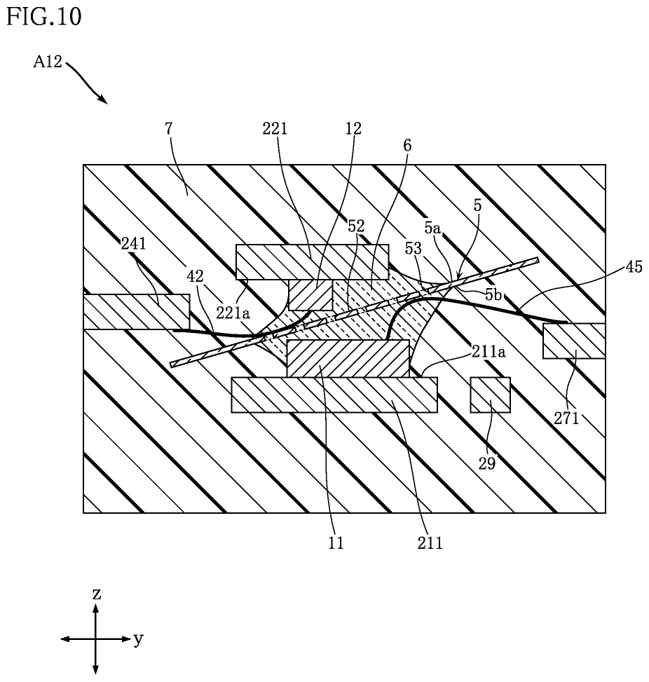

FIG. 10 shows a semiconductor device according to a second variation of the first embodiment. FIG. 10 is a sectional view similar to FIG. 6 shown in the above-described embodiment. The semiconductor device A12 of the present variation differs from the above-described embodiment in configuration of the first sheet 5. In the present variation, the first sheet 5 is not provided with the uneven portion 51. The first sheet 5 is covered with the transparent resin 6 and the sealing resin 7. Each opening 53 of the first sheet 5 is filled with the transparent resin 6.

Such a configuration improves the adhesion between the portion of the first sheet 5 that is formed with the openings 53 and the transparent resin 6 (resin part). Thus, the portion of the first sheet 5 that is formed with the openings 53 is prevented from separating from the transparent resin 6, whereby a decrease in the dielectric strength is further suppressed. Additionally, the same effect as the semiconductor device A10 of the above-described embodiment is also provided owing to the configuration in common with the above-described embodiment.

### Third Variation of the First Embodiment

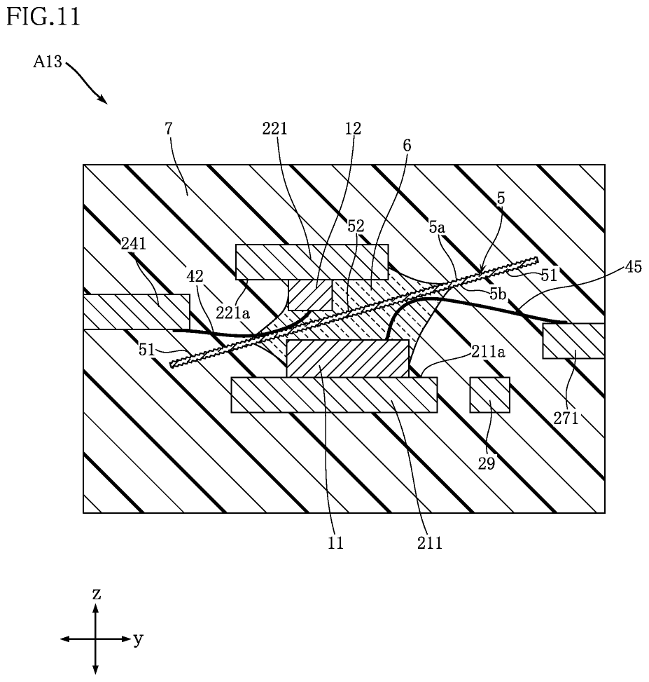

FIG. 11 shows a semiconductor device according to a third variation of the first embodiment. FIG. 11 is a sectional view similar to FIG. 6 shown in the above-described embodiment. The semiconductor device A13 of the present variation differs from the above-described embodiment in configuration of the first sheet 5. In the present variation, the first sheet 5 is entirely provided with the uneven portion 51 and is not formed with openings 53. More specifically, the entirety of each of the first surface 5a and the second surface 5b is the uneven portion 51 with irregularities. The first sheet 5 is covered with the transparent resin 6 and the sealing resin 7.

With such a configuration, the irregular portion 51 of the first sheet 5, which comes into contact with the transparent resin 6 or the sealing resin 7, has improved adhesion to the transparent resin 6 or the sealing resin 7. This prevents the first sheet 5 from separating from the transparent resin 6 or the sealing resin 7 covering it and suppresses a decrease in the dielectric strength. In the present variation, the entirety of each of the first surface 5a and the second surface 5b is the irregular portion 51. Thus, the adhesion between the first sheet 5 and the transparent resin 6 or the sealing resin 7 is further improved. This is more favorable for suppressing a decrease in the dielectric strength. Additionally, the same effect as the semiconductor device A10 of the above-described embodiment is also provided owing to the configuration in common with the above-described embodiment.

In the semiconductor devices A10, A11, A12 and A13 described above, the uneven portion 51 of the first sheet 5 is provided on both the first surface 5a and the second surface 5b. However, the uneven portion 51 may be provided on only one of the first surface 5a and the second surface 5b. Additionally, although each of the semiconductor devices A10, A11, A12 and A13 is a configuration example that includes two each of the light-receiving element 11 and light-emitting element 12, a configuration that includes one each of the light-receiving element 11 and the light-emitting element 12 may be employed. In this case, some of the leads 21 to 28 constituting the conductive support 2 are so-called dummy terminals and are not electrically connected to either the light-receiving element 11 or the light-emitting element 12.

### Second Embodiment

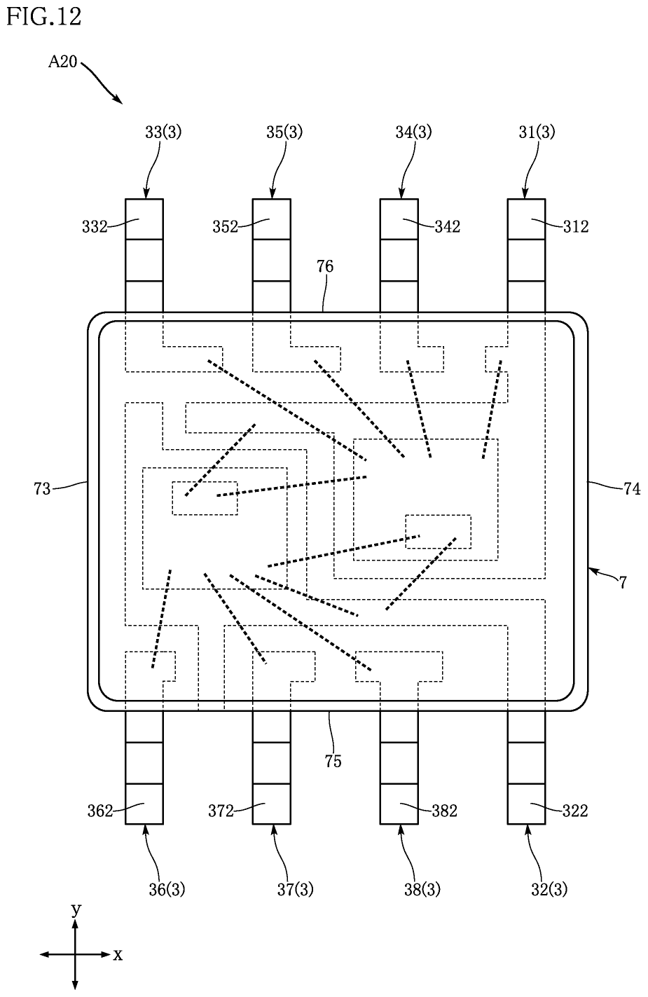

The semiconductor device A20 according to a second embodiment of the present disclosure will be described based on FIGS. 12 to 17. The semiconductor device A20 of the present embodiment includes light-receiving elements 11, light-emitting elements 12, a conductive support 3, a plurality of wires 4, first sheets 5, transparent resins 6, and a sealing resin 7. The present embodiment differs largely from the above-described embodiment in arrangement of the light-receiving elements 11 and the light-emitting elements 12. Along with this, a conductive support 3 is provided instead of the conductive support 2 of the above-described embodiment.

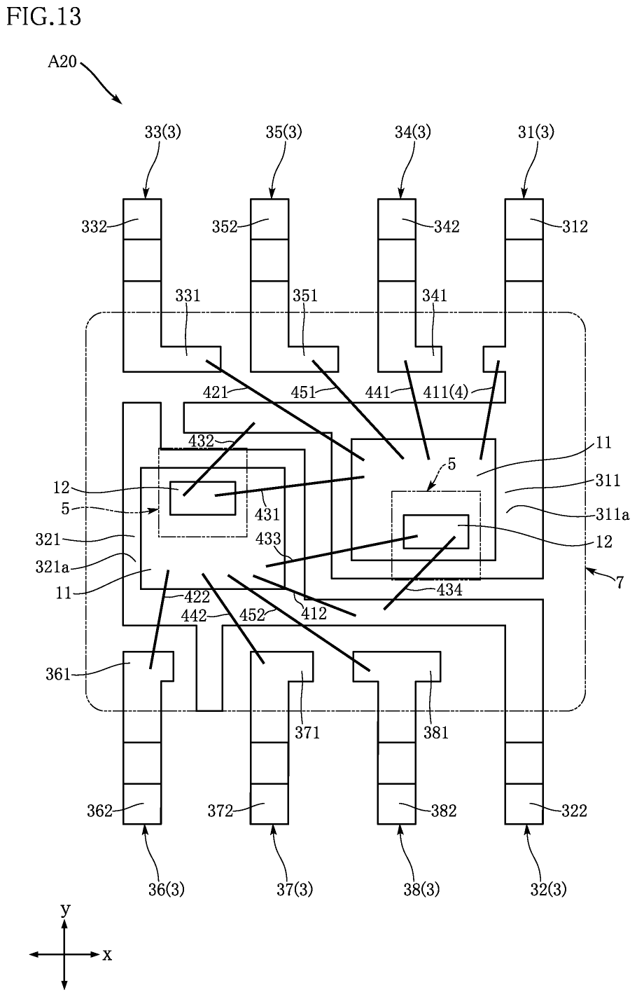

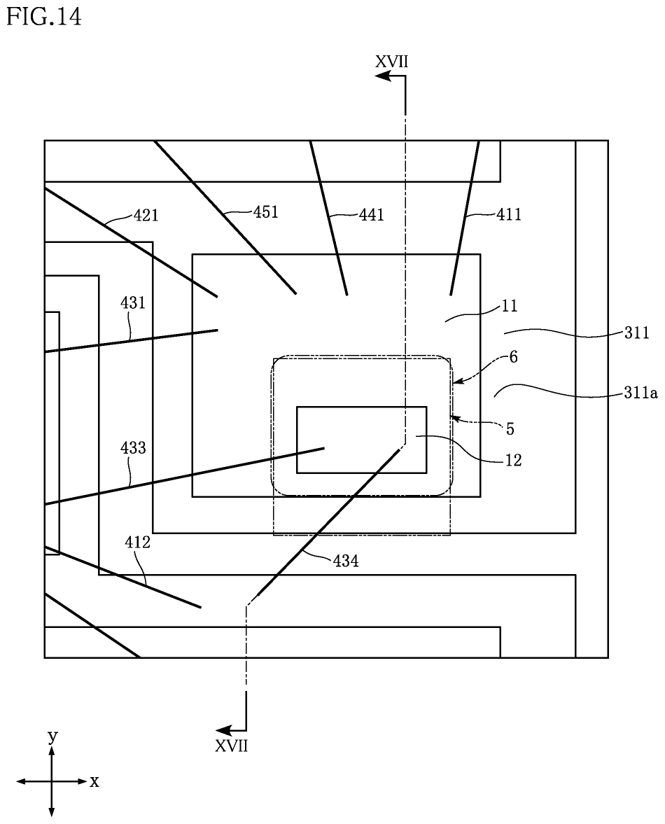

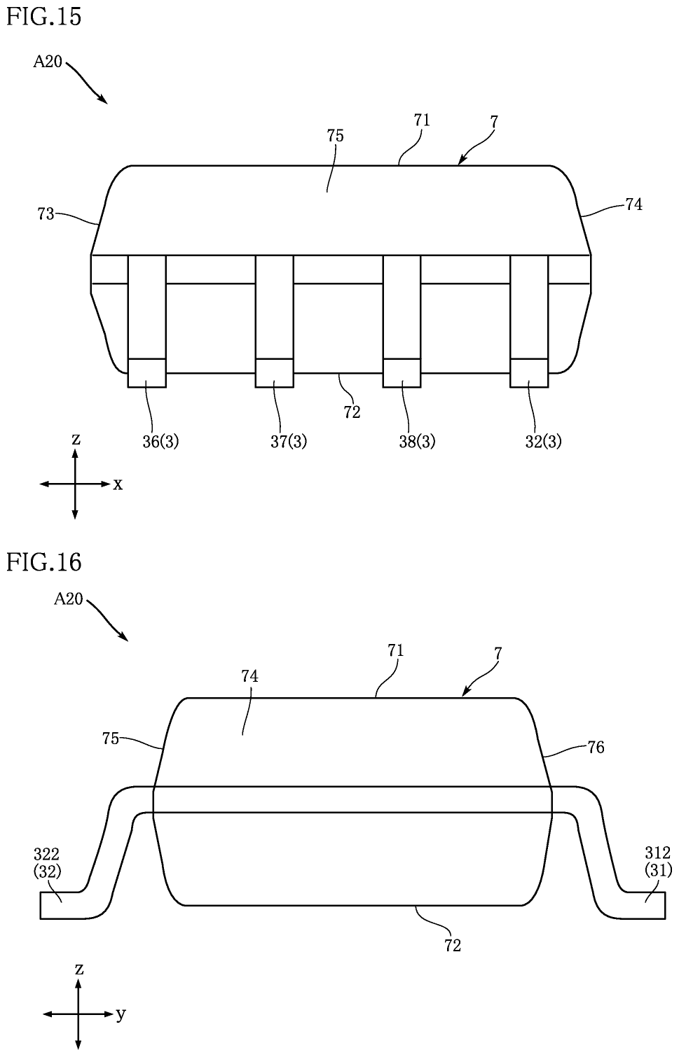

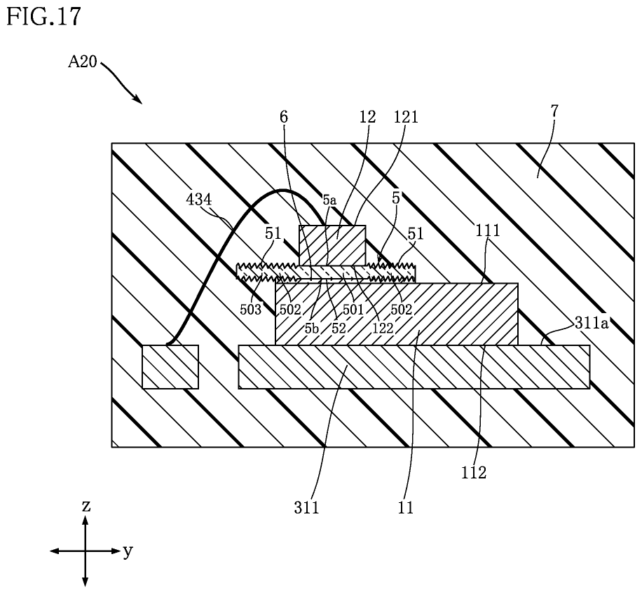

FIG. 12 is a plan view showing the semiconductor device A20. FIG. 13 is a plan view showing the semiconductor device A20. For the convenience of understanding, in FIG. 13, the first sheets 5 and the sealing resin 7 are transparent, and the outlines of these are indicated by imaginary lines (dash-double dot lines). FIG. 14 is a partial enlarged view of FIG. 13. FIG. 15 is a front view of the semiconductor device A20. FIG. 16 is a right side view of the semiconductor device A20. FIG. 17 is a sectional view taken along line XVII-XVII in FIG. 14.

As shown in FIG. 17, in the present embodiment, the first sheet 5 and the light-emitting element 12 are stacked on the first side in the thickness direction z with respect to the light-receiving element 11. Note that the semiconductor device A20 of the present embodiment includes two light-receiving elements 11 and two light-emitting elements 12 as shown in FIG. 13. One first sheet 5 is disposed between each light-receiving element 11 and a corresponding light-emitting element 12 that are paired in the thickness direction z.

As shown in FIG. 17, the first sheet 5 is interposed between the obverse surface 111 of the light-receiving element 11 and the reverse surface 122 of the light-emitting element 12 in the thickness direction z. The first sheet 5 includes a first region 501, a second region 502, and a third region 503. The first region 501 is the portion that overlaps with both the light-receiving element 11 and the light-emitting element 12 as viewed in the thickness direction z. The second region 502 is the portion that overlaps with the light-receiving element 11 and does not overlap with the light-emitting element 12 as viewed in the thickness direction z. The third region 503 is the portion that does not overlap with either the light-receiving element 11 or the light-emitting element 12 as viewed in the thickness direction z. As will be described later, a transparent resin 6 is interposed between the light-receiving element 11 and the first sheet 5.

The conductive support 3 is an electrically conductive member that forms conduction paths between the light-receiving and the light-emitting elements 11 and 12 and the circuit board on which the semiconductor device A20 is mounted. The conductive support 3 includes leads 31 to 38. The leads 31 to 38 are spaced apart from each other.

The lead 31 supports a light-receiving element 11 and is electrically connected to the light-receiving element 11. The lead 31 includes a first die pad 311 and a terminal portion 312. As shown in FIG. 13, the first die pad 311 is disposed at a position offset toward the first side in the direction x at the center (or approximately the center) of the semiconductor device A20 in the direction y. As shown in FIGS. 13 and 14, the first die pad 311 carries a first one of the two light-receiving elements 11. The first die pad 311 is rectangular (or generally rectangular) as viewed in the thickness direction z. The first die pad 311 is electrically connected to the light-receiving element 11 via a wire 4 (wire 411 described later). The first die pad 311 is covered with the sealing resin 7.

As shown in FIGS. 13, 14 and 17, the first die pad 311 has a first obverse surface 311a. The first obverse surface 311a faces the first side in the thickness direction z. The first obverse surface 311a is generally flat. The first one of the two light-receiving elements 11 is bonded to the first obverse surface 311a.

As shown in FIG. 13, the terminal portion 312 is connected to the first die pad 311 on the first side in the direction y (the upper side in FIG. 13) and extends toward the first side in the direction y to be partially exposed from the sealing resin 7. The terminal portion 312 is electrically connected to the light-receiving element 11 via the first die pad 311 and the wire 411. As shown in FIG. 16, the portion of the terminal portion 312 that is exposed from the sealing resin 7 is bent into a hook shape as viewed in the direction x. The shape of the lead 31 is not limited to the above.

The lead 32 supports a light-receiving element 11 and is electrically connected to the light-receiving element 11. The lead 32 includes a first die pad 321 and a terminal portion 322. As shown in FIG. 13, the first die pad 321 is disposed at a position offset toward the second side in the direction x at the center (or approximately the center) of the semiconductor device A20 in the direction y. As shown in FIG. 13, the first die pad 321 carries a second one of the two light-receiving elements 11. The first die pad 321 is rectangular (or generally rectangular) as viewed in the thickness direction z. The first die pad 321 is electrically connected to the light-receiving element 11 via a wire 4 (wire 412 described later). The first die pad 321 is covered with the sealing resin 7.

As shown in FIG. 13, the first die pad 321 has a first obverse surface 321a. The first obverse surface 321a faces the first side in the thickness direction z. The first obverse surface 321a is flat (or generally flat). The second one of the two light-receiving elements 11 is bonded to the first obverse surface 321a.

As shown in FIG. 13, the terminal portion 322 is connected to the first die pad 321 on the second side in the direction y (the lower side in FIG. 13) and extends toward the second side in the direction y to be partially exposed from the sealing resin 7. The terminal portion 322 is electrically connected to the light-receiving element 11 via the first die pad 321 and the wire 412. As shown in FIG. 16, the portion of the terminal portion 322 that is exposed from the sealing resin 7 is bent into a hook shape as viewed in the direction x. The shape of the lead 32 is not limited to the above.

The lead 33 is electrically connected to a light-receiving element 11. The lead 33 includes a pad portion 331 and a terminal portion 332.

The pad portion 331 is disposed on the second side in the direction x and the first side in the direction y in the semiconductor device A20. The pad portion 331 is electrically connected to a light-receiving element 11 (the light-receiving element 11 mounted on the first die pad 311) via a wire 4 (wire 421 described later). The pad portion 331 is covered with the sealing resin 7. The pad portion 331 is rectangular (or generally rectangular) as viewed in the thickness direction z. The wire 421 is bonded to the pad portion 331.

As shown in FIG. 13, the terminal portion 332 is connected to the pad portion 331 on the first side in the direction y (the upper side in FIG. 13) and extends toward the first side in the direction y to be partially exposed from the sealing resin 7. The terminal portion 332 is electrically connected to the light-receiving element 11 via the pad portion 331 and the wire 421. The portion of the terminal portion 332 that is exposed from the sealing resin 7 is bent into a hook shape as viewed in the direction x. The shape of the lead 33 is not limited to the above.

The lead 34 is electrically connected to a light-receiving element 11. The lead 34 includes a pad portion 341 and a terminal portion 342.

The pad portion 341 is disposed on the first side in the direction y with respect to the first die pad 311. The pad portion 341 is electrically connected to a light-receiving element 11 (the light-receiving element 11 mounted on the first die pad 311) via a wire 4 (wire 441 described later). The pad portion 341 is covered with the sealing resin 7. The pad portion 341 is rectangular (or generally rectangular) as viewed in the thickness direction z. The wire 441 is bonded to the pad portion 341.

As shown in FIG. 13, the terminal portion 342 is connected to the pad portion 341 on the first side in the direction y and extends toward the first side in the direction y to be partially exposed from the sealing resin 7. The terminal portion 342 is electrically connected to the light-receiving element 11 via the pad portion 341 and the wire 441. The portion of the terminal portion 342 that is exposed from the sealing resin 7 is bent into a hook shape as viewed in the direction x. The shape of the lead 34 is not limited to the above.

The lead 35 is electrically connected to a light-receiving element 11. The lead 35 includes a pad portion 351 and a terminal portion 352.

The pad portion 351 is disposed between the pad portion 331 and the pad portion 341 in the direction x. The pad portion 351 is electrically connected to a light-receiving element 11 (the light-receiving element 11 mounted on the first die pad 311) via a wire 4 (wire 451 described later). The pad portion 351 is covered with the sealing resin 7. The pad portion 351 is rectangular (or generally rectangular) as viewed in the thickness direction z. The wire 451 is bonded to the pad portion 351.

The terminal portion 352 is connected to the pad portion 351 on the first side in the direction y and extends toward the first side in the direction y to be partially exposed from the sealing resin 7. The terminal portion 352 is electrically connected to the light-receiving element 11 via the pad portion 351 and the wire 451. The portion of the terminal portion 352 that is exposed from the sealing resin 7 is bent into a hook shape as viewed in the direction x. The shape of the lead 35 is not limited to the above.

As shown in FIG. 12, the terminal portions 332, 352, 342, and 312 protrude from the resin side surface 76 of the sealing resin 7 on the first side in the direction y and are arranged at equal intervals in this order from the second side toward the first side in the direction x.

The lead 36 is electrically connected to a light-receiving element 11. The lead 36 includes a pad portion 361 and a terminal portion 362.

The pad portion 361 is disposed on the second side in the direction x and the second side in the direction y in the semiconductor device A20. The pad portion 361 is electrically connected to a light-receiving element 11 (the light-receiving element 11 mounted on the first die pad 321) via a wire 4 (wire 422 described later). The pad portion 361 is covered with the sealing resin 7. The pad portion 361 is rectangular (or generally rectangular) as viewed in the thickness direction z. The wire 422 is bonded to the pad portion 361.

As shown in FIG. 13, the terminal portion 362 is connected to the pad portion 361 on the second side in the direction y (the lower side in FIG. 13) and extends toward the second side in the direction y to be partially exposed from the sealing resin 7. The terminal portion 362 is electrically connected to the light-receiving element 11 via the pad portion 361 and the wire 422. The portion of the terminal portion 362 that is exposed from the sealing resin 7 is bent into a hook shape as viewed in the direction x. The shape of the lead 36 is not limited to the above.

The lead 37 is electrically connected to a light-receiving element 11. The lead 37 includes a pad portion 371 and a terminal portion 372.

The pad portion 371 is disposed on the first side in the direction x with respect to the pad portion 361. The pad portion 371 is electrically connected to a light-receiving element 11 (the light-receiving element 11 mounted on the first die pad 321) via a wire 4 (wire 442 described later). The pad portion 371 is covered with the sealing resin 7. The pad portion 371 is rectangular (or generally rectangular) as viewed in the thickness direction z. The wire 442 is bonded to the pad portion 371.

The terminal portion 372 is connected to the pad portion 371 on the second side in the direction y and extends toward the second side in the direction y to be partially exposed from the sealing resin 7. The terminal portion 372 is electrically connected to the light-receiving element 11 via the pad portion 371 and the wire 442. The portion of the terminal portion 372 that is exposed from the sealing resin 7 is bent into a hook shape as viewed in the direction x. The shape of the lead 37 is not limited to the above.

The lead 38 is electrically connected to a light-receiving element 11. The lead 38 includes a pad portion 381 and a terminal portion 382.

The pad portion 381 is disposed on the first side in the direction x with respect to the pad portion 371. The pad portion 381 is electrically connected to a light-receiving element 11 (the light-receiving element 11 mounted on the first die pad 321) via a wire 4 (wire 452 described later). The pad portion 381 is covered with the sealing resin 7. The pad portion 381 is rectangular (or generally rectangular) as viewed in the thickness direction z. The wire 452 is bonded to the pad portion 381.

The terminal portion 382 is connected to the pad portion 381 on the second side in the direction y and extends toward the second side in the direction y to be partially exposed from the sealing resin 7. The terminal portion 382 is electrically connected to the light-receiving element 11 via the pad portion 381 and the wire 452. The portion of the terminal portion 382 that is exposed from the sealing resin 7 is bent into a hook shape as viewed in the direction x. The shape of the lead 38 is not limited to the above.

As shown in FIG. 12, the terminal portions 362, 372, 382, and 322 protrude from the resin side surface 75 of the sealing resin 7 on the second side in the direction y and are arranged at equal intervals in this order from the second side toward the first side in the direction x.

The light-emitting elements 12 are rectangular as viewed in the thickness direction z. As shown in FIG. 17, the light-emitting element 12 has an obverse surface 121 and a reverse surface 122. The obverse surface 121 faces the first side in the thickness direction z. The reverse surface 122 faces the second side in the thickness direction z. The light-emitting element 12 is provided with a cathode electrode and an anode electrode (both not shown) disposed on the obverse surface 121.

The first one of the light-emitting elements 12 shown in FIG. 17 and the second one of the light-emitting elements 12 are bonded to the first surfaces 5a of the first sheets 5 via a bonding material, not shown. The bonding material is not particularly limited and may be a light-passing bonding material having insulating properties, for example. The light-emitting elements 12 are bonded at their reverse surfaces 122 to the first surfaces 5a of the first sheets 5 with a bonding material. As shown in FIG. 13, the anode electrode of the first one (on the right side in FIG. 13) of the light-emitting elements 12 is electrically connected to the terminal portion 382 via wires 4 (wires 433 and 452 described later). The cathode electrode of the first one of the light-emitting elements 12 is electrically connected to the terminal portion 322 via a wire 4 (wire 434 described later). The anode electrode of the second one (on the left side in FIG. 13) of the light-emitting elements 12 is electrically connected to the terminal portion 352 via wires 4 (wires 431 and 451 described later). The cathode electrode of the second one of the light-emitting elements 12 is electrically connected to the terminal portion 312 via a wire 4 (wire 432 described later).

The light-emitting elements 12 have their reverse surfaces 122 covered with the first sheets 5. Portions of each light-emitting element 12 other than the reverse surface 122 are covered with the sealing resin 7. Each light-emitting element 12 emits light in response to a current that flows when a voltage is applied between the anode electrode and the cathode electrode. The light emitted from the light-emitting element 12 travels mainly from the reverse surface 122 to the first sheet 5 to reach the light-receiving element 11 through the transparent resin 6.

The light-receiving elements 11 receive the light emitted from the light-emitting elements 12 stacked thereon. The first one of the light-receiving elements 11 shown in FIG. 17 and the second one of the light-receiving elements 11 are bonded to the first obverse surfaces 311a and 321a of the first die pads 311 and 321, respectively, via a bonding material, not shown. The bonding material is not particularly limited and may be an insulating bonding material. The light-receiving elements 11 are bonded at their reverse surfaces 112 to the first obverse surfaces 311a and 321a of the first die pads 311 and 321.

Each light-receiving element 11 has a light-receiving section and a circuit forming section (both not shown) disposed on the obverse surface 111. The light-receiving section is located at a position overlapping with the light-emitting element 12 in the thickness direction z. The light-receiving section has a photodiode, for example, and generates an electromotive force in accordance with the amount of light received. On the light-receiving section of the light-receiving element 11, a transparent resin 6, a first sheet 5 and a light-emitting element 12 are stacked in this order in the thickness direction z. Thus, the light-receiving section can properly receive the light emitted from the light-emitting element 12 through the first sheet 5 and the transparent resin 6.

The circuit forming section amplifies the electromotive force generated by the light-receiving section receiving light, and outputs it. The circuit forming section has a plurality of electrodes disposed therein. As shown in FIG. 13, the electrodes are electrically connected to the leads 31, 33, 34, and 35, or the leads 32, 36, 37, and 38 via wires 4. Specifically, the power supply electrodes of the light-receiving elements 11 are electrically connected to the pad portions 331 and 361 of the leads 33 and 36 via the wires 421 and 422. Thus, the terminal portions 332 and 362 of the leads 33 and 36 electrically conduct to the power supply electrodes of the light-receiving elements 11 to function as power supply terminals. The ground electrodes of the light-receiving elements 11 are electrically connected to the terminal portions 312 and 322 of the leads 31 and 32 via the wires 411 and 412. Thus, the terminal portions 312 and 322 of the leads 31 and 32 electrically conduct to the ground electrodes of the light-receiving elements 11 to function as ground terminals. The output electrodes of the light-receiving elements 11 are electrically connected to the pad portions 341 and 371 of the leads 34 and 37 via the wires 441 and 442. Thus, the terminal portions 342 and 372 of the leads 34 and 37 are electrically connected to the output electrodes of the light-receiving elements 11 to function as output terminals.

When a voltage is applied between the terminal portion 382 or 352 and the terminal portion 322 or 312, a voltage is applied between the anode electrode and the cathode electrode of the light-emitting element 12, causing a current to flow. As a result, the light-emitting element 12 emits light. The light-receiving section of the light-receiving element 11, when receives light, generates an electromotive force corresponding to the amount of light received. The electromotive force is amplified in the circuit forming section by the power supplied between the terminal portion 332 or 362 and the terminal portion 312 or 322 and then outputted from the terminal portion 342 or 372. In this way, the semiconductor device A20 is capable of transmitting signals from the input side (terminal portions 382 or 352 and terminal portion 322 or 312) to the output side (terminal portions 342 or 372) while the input side and the output side are electrically insulated from each other.

As shown in FIGS. 13 and 14, the wires 4 are conductive members that form, with the conductive support 3, conduction paths between the light-emitting and the light-receiving elements 12 and 11 and a circuit board. The wires 4 include wires 411, 412, 421, 422, 431, 432, 433, 434, 441, 442, 451 and 452.

The wires 411 and 412 form conduction paths between the light-receiving elements 11 and the leads 31 and 32. The wires 411 and 412 are bonded to the ground electrodes of the light-receiving elements 11 and the terminal portions 312 and 322. The number of wires 411 and 412 is not limited. The wires 421 and 422 are bonded to the power supply electrodes of the light-receiving elements 11 and the pad portions 331 and 361 of the leads 33 and 36. The number of wires 421 and 422 is not limited. The wires 431 and 433 are bonded to the anode electrodes of the light-emitting elements 12 and the light-receiving elements 11. The number of wires 431 and 433 is not limited. The wires 432 and 434 are bonded to the cathode electrodes of the light-emitting elements 12 and the leads 31 and 32. The number of wires 432 and 434 is not limited. The wires 441 and 442 are bonded to the output electrodes of the light-receiving elements 11 and the pad portions 341 and 371 of the leads 34 and 37. The number of wires 441 and 442 is not limited. The wires 451 and 452 are bonded to the light-receiving elements 11 and the pad portions 351 and 381 of the leads 35 and 38. The number of wires 451 and 452 is not limited.

As shown in FIG. 13, the first sheets 5 are rectangular as viewed in the thickness direction z. Each first sheet 5 overlaps with a portion of a light-receiving element 11, a portion of the first die pad 311 or 321, and the entirety of a light-emitting element 12, as viewed in the thickness direction z. The light emitted from the light-emitting element 12 passes through the first sheet 5 located between the light-emitting element and the light-receiving element 11 supporting the light-emitting element 12. The shape of the first sheet 5 is not limited to the above.

In the present embodiment, each first sheet 5 has an uneven portion 51 and a flat portion 52. In the present embodiment, the uneven portion 51 is a portion where at least a portion of the first surface 5a and the second surface 5b is made irregular. The shape, arrangement, and height of the irregularities of the uneven portion 51 are not limited.

In the present embodiment, the uneven portion 51 is provided in the second region 502 and the third region 503 of the first sheet 5. The uneven portion 51 is provided on both the first surface 5a and the second surface 5b in the second region 502 and the third region 503. Preferably, the uneven portion 51 has a surface roughness greater than a predetermined value. The uneven portion 51 has a surface area that is, for example, 1.5 times or greater than the surface area when no irregularities are formed. Although no upper limit is specified here, as in “1.5 times or greater”, it is preferable that the surface area of the uneven portion 51 is not greater than 2.5 times the surface area when no irregularities are formed, so that an inconvenience such as the thickness of the first sheet 5 becoming extremely uneven can be prevented. It is preferable that the uneven portion 51 is provided at least in the second region 502. In the present embodiment, the flat portion 52 is provided in the first region 501 of the first sheet 5. Unlike the present embodiment, the uneven portion 51 may be provided in all of the first region 501, the second region 502 and the third region 503 of the first sheet 5, and the flat portion 52 may not be provided.

In the present embodiment, the transparent resins 6 are interposed between the light-receiving elements 11 and the first sheets 5. Each transparent resin 6 is held in contact with a portion of the obverse surface 111 of a light-receiving element 11, and the second surface 5b in the second region 502 formed with the uneven portion 51 and the second surface 5b in the first region 501 which is the flat portion 52 of the first sheet 5.

The sealing resin 7 covers portions of the conductive support 3, the light-receiving elements 11, the light-emitting elements 12, the wires 4, portions of the first sheets 5, and the transparent resins 6. More specifically, the sealing resin 7 covers the first surface 5a in the second region 502 formed with the uneven portion 51 and the first surface 5a and the second surface 5b in the third region 503 formed with the uneven portion 51 of the first sheet 5.

The effects of the present embodiment will be described.

The semiconductor device A20 includes the light-receiving elements 11, the light-emitting elements 12, the first sheets 5, the transparent resins 6, and the sealing resin 7. The light-receiving elements 11 are mounted on the first obverse surfaces 311a and 321a of the first die pads 311 and 321 that face the first side in the thickness direction z. The light-emitting elements 12 are located on the first side in the thickness direction z with respect to the light-receiving elements 11. Each first sheet 5 has the first surface 5a and the second surface 5b facing the first side and the second side in the thickness direction z. Each first sheet 5 allows light to pass through and has insulating properties, and is interposed between a light-receiving element 11 and a light-emitting element 12 in the thickness direction z. The first sheets 5 are covered with the transparent resin 6 and the sealing resin 7. At least a portion of the first surface 5a and the second surface 5b of each first sheet 5 includes the uneven portion 51 with irregularities.

With such a configuration, the irregular portions 51 of the first sheets 5, which come into contact with the transparent resins 6 or the sealing resin 7, have improved adhesion to the transparent resin 6 or the sealing resin 7. This prevents the first sheets 5 from separating from the transparent resins 6 or the sealing resin 7 covering them and suppresses a decrease in the dielectric strength.

The first sheet 5 and the light-emitting element 12 are stacked on the first side in the thickness direction z with respect to the light-receiving element 11. The transparent resin 6 is interposed between the light-receiving element 11 and the first sheet 5. The uneven portion 51 is provided at least in the second region 502 of the first sheet 5. The second region 502 is the portion that overlaps with the light-receiving element 11 and does not overlap with the light-emitting element 12 as viewed in the thickness direction z and surrounds the light-emitting element 12 as viewed in the thickness direction z. With such a configuration, the second region 502 that surrounds the light-emitting element 12 as viewed in the thickness direction z has improved adhesion to the transparent resin 6 or the sealing resin 7. Thus, the first sheet 5 is properly prevented from separating from the transparent resin 6 or the sealing resin 7.

In the semiconductor device A20, the uneven portion 51 is provided in the third region 503 of the first sheet 5 as well. With such a configuration, the third region 503 is also prevented from separating from the sealing resin 7, whereby a decrease in the dielectric strength is further suppressed.

The semiconductor device according to the present disclosure is not limited to the foregoing embodiments. The specific configuration of each part of the semiconductor device according to the present disclosure may be varied in design in many ways.

The present disclosure includes the embodiments described in the following clauses.

### Clause 1.

A semiconductor device comprising:
a first die pad including a first obverse surface facing a first side in a thickness direction;
a light-receiving element mounted on the first obverse surface;
a light-emitting element disposed on the first side in the thickness direction with respect to the light-receiving element;
a first sheet with light-passing and insulating properties interposed between the light-receiving element and the light-emitting element in the thickness direction; and
a resin part covering the light-receiving element, the light-emitting element and the first sheet, wherein
the first sheet includes a first surface facing the first side in the thickness direction and a second surface facing away from the first surface, and
at least a portion of the first surface and the second surface includes an uneven portion with irregularities.

### Clause 2.

The semiconductor device according to clause 1, wherein the light-emitting element overlaps with the light-receiving element as viewed in the thickness direction.

### Clause 3.

The semiconductor device according to clause 1 or 2, further comprising a second die pad disposed on the first side in the thickness direction with respect to the first die pad while being spaced apart from the first die pad, wherein
the second die pad includes a second obverse surface facing the second side in the thickness direction and facing the first obverse surface,
the light-emitting element is mounted on the second obverse surface, and
the resin part includes a transparent resin and a sealing resin, the transparent resin covering at least a portion of each of the light-receiving element and the light-emitting element and a portion of the first sheet, the sealing resin covering the transparent resin and a portion of the first sheet.

### Clause 4.

The semiconductor device according to clause 3, wherein the uneven portion is held in contact with the sealing resin.

### Clause 5.

The semiconductor device according to clause 4, wherein the first surface and the second surface each include a flat portion that is flatter than the uneven portion, and
the transparent resin is held in contact with only the flat portion of the first surface and the second surface.

### Clause 6.

The semiconductor device according to any one of clauses 3 to 5, wherein the first sheet is formed with one or more openings each penetrating from the first surface to the second surface, and each of the openings is filled with the resin part.

### Clause 7.

The semiconductor device according to clause 6, wherein each of the openings is filled with the transparent resin.

### Clause 8.

The semiconductor device according to clause 6 or 7, further comprising a wire bonded to the light-receiving element or the light-emitting element.

### Clause 9.

The semiconductor device according to clause 8, wherein as viewed in the thickness direction, a dimension of each of the openings in a direction in which the wire extends is in a range of 0.5 to 2 times a diameter of the wire.

### Clause 10.

The semiconductor device according to clause 2, wherein the first sheet and the light-emitting element are stacked on the first side in the thickness direction with respect to the light-receiving element.

### Clause 11.

The semiconductor device according to clause 10, wherein the first sheet includes a first region, a second region and a third region, the first region overlapping with both the light-receiving element and the light-emitting element as viewed in the thickness direction, the second region overlapping with the light-receiving element and not overlapping with the light-emitting element as viewed in the thickness direction, the third region not overlapping with either the light-receiving element or the light-emitting element as viewed in the thickness direction, and
the uneven portion is provided at least in the second region.

### Clause 12.

The semiconductor device according to clause 10 or 11, wherein the resin part includes a transparent resin and a sealing resin, the transparent resin being interposed between the light-receiving element and the first sheet in the thickness direction, the sealing resin covering the light-receiving element, the light-emitting element, the first sheet and the transparent resin.

### Clause 13.

The semiconductor device according to any one of clauses 1 to 12, wherein the uneven portion has a surface area that is 1.5 times or greater than a surface area when no irregularities are formed.

### Clause 14.

A semiconductor device comprising:
a first die pad including a first obverse surface facing a first side in a thickness direction;
a light-receiving element mounted on the first obverse surface;
a second die pad disposed on the first side in the thickness direction with respect to the first die pad while being spaced apart from the first die pad and including a second obverse surface facing the second side in the thickness direction and facing the first obverse surface;
a light-emitting element mounted on the second obverse surface;
a first sheet with light-passing and insulating properties interposed between the light-receiving element and the light-emitting element in the thickness direction; and
a resin part covering the light-receiving element, the light-emitting element and the first sheet, wherein
the first sheet includes a first surface facing the first side in the thickness direction and a second surface facing away from the first surface,
the resin part includes a transparent resin and a sealing resin, the transparent resin covering at least a portion of each of the light-receiving element and the light-emitting element and a portion of the first sheet, the sealing resin covering the transparent resin and a portion of the first sheet,
the first sheet is formed with one or more openings each penetrating from the first surface to the second surface, and
each of the openings is filled with the resin part.

### Clause 15.

The semiconductor device according to clause 14, wherein each of the openings is filled with the transparent resin.

### Clause 16.

The semiconductor device according to clause 15, further comprising a wire bonded to the light-receiving element or the light-emitting element,
wherein as viewed in the thickness direction, a dimension of each of the openings in a direction in which the wire extends is in a range of 0.5 to 2 times a diameter of the wire.

### REFERENCE NUMERALS

A10, A11, A12, A13, A20: Semiconductor device
11: Light-receiving element 111: Obverse surface
112: Reverse surface 12: Light-emitting element
121: Obverse surface 122: Reverse surface
2: Conductive support 21: Lead
211: First die pad 211a: First obverse surface
212: Terminal portion 22: Lead
221: Second die pad 221a: Second obverse surface
222: Terminal portion 23: Lead
231: Pad portion 232: Terminal portion
24: Lead 242: Terminal portion
25: Lead 252: Terminal portion
26: Lead 261: Pad portion
262: Terminal portion 27: Lead
271: Pad portion 272: Terminal portion
28: Lead 281: Pad portion
282: Terminal portion 29: Lead
3: Conductive support 31: Lead
311: First die pad 311a: First obverse surface
312: Terminal portion 32: Lead
321: First die pad 321a: First obverse surface
322: Terminal portion 33: Lead
331: Pad portion 332: Terminal portion
34: Lead 342: Terminal portion
35: Lead 352: Terminal portion
36: Lead 361: Pad portion
362: Terminal portion 37: Lead
371: Pad portion 372: Terminal portion
38: Lead 381: Pad portion
382: Terminal portion
4, 41 to 48, 411, 412, 421, 422, 431: Wire
432, 433, 434, 441, 442, 451, 452: Wire
5: First sheet 5a: First surface
5b: Second surface 501: First region
502: Second region 503: Third region
51: Uneven portion 52: Flat portion
53: Opening 6: Transparent resin
7: Sealing resin 71: Resin top surface
72: Resin bottom surface 73t o76: Resin side surface

1. A semiconductor device comprising:
a first die pad including a first obverse surface facing a first side in a thickness direction;
a light-receiving element mounted on the first obverse surface;
a light-emitting element disposed on the first side in the thickness direction with respect to the light-receiving element;
a first sheet with light-passing and insulating properties interposed between the light-receiving element and the light-emitting element in the thickness direction; and
a resin part covering the light-receiving element, the light-emitting element and the first sheet, wherein
the first sheet includes a first surface facing the first side in the thickness direction and a second surface facing away from the first surface, and
at least a portion of the first surface and the second surface includes an uneven portion with irregularities.

2. The semiconductor device according to claim 1, wherein the light-emitting element overlaps with the light-receiving element as viewed in the thickness direction.

3. The semiconductor device according to claim 1, further comprising a second die pad disposed on the first side in the thickness direction with respect to the first die pad while being spaced apart from the first die pad, wherein
the second die pad includes a second obverse surface facing the second side in the thickness direction and facing the first obverse surface,
the light-emitting element is mounted on the second obverse surface, and
the resin part includes a transparent resin and a sealing resin, the transparent resin covering at least a portion of each of the light-receiving element and the light-emitting element and a portion of the first sheet, the sealing resin covering the transparent resin and a portion of the first sheet.

4. The semiconductor device according to claim 3, wherein the uneven portion is held in contact with the sealing resin.

5. The semiconductor device according to claim 4, wherein the first surface and the second surface each include a flat portion that is flatter than the uneven portion, and
the transparent resin is held in contact with only the flat portion of the first surface and the second surface.

6. The semiconductor device according to claim 3, wherein the first sheet is formed with one or more openings each penetrating from the first surface to the second surface, and
each of the openings is filled with the resin part.

7. The semiconductor device according to claim 6, wherein each of the openings is filled with the transparent resin.

8. The semiconductor device according to claim 6, further comprising a wire bonded to the light-receiving element or the light-emitting element.

9. The semiconductor device according to claim 8, wherein as viewed in the thickness direction, a dimension of each of the openings in a direction in which the wire extends is in a range of 0.5 to 2 times a diameter of the wire.

10. The semiconductor device according to claim 2, wherein the first sheet and the light-emitting element are stacked on the first side in the thickness direction with respect to the light-receiving element.

11. The semiconductor device according to claim 10, wherein the first sheet includes a first region, a second region and a third region, the first region overlapping with both the light-receiving element and the light-emitting element as viewed in the thickness direction, the second region overlapping with the light-receiving element and not overlapping with the light-emitting element as viewed in the thickness direction, the third region not overlapping with either the light-receiving element or the light-emitting element as viewed in the thickness direction, and
the uneven portion is provided at least in the second region.

12. The semiconductor device according to claim 10, wherein the resin part includes a transparent resin and a sealing resin, the transparent resin being interposed between the light-receiving element and the first sheet in the thickness direction, the sealing resin covering the light-receiving element, the light-emitting element, the first sheet and the transparent resin.

13. The semiconductor device according to claim 1, wherein the uneven portion has a surface area that is 1.5 times or greater than a surface area when no irregularities are formed.

14. A semiconductor device comprising:
a first die pad including a first obverse surface facing a first side in a thickness direction;
a light-receiving element mounted on the first obverse surface;
a second die pad disposed on the first side in the thickness direction with respect to the first die pad while being spaced apart from the first die pad and including a second obverse surface facing the second side in the thickness direction and facing the first obverse surface;
a light-emitting element mounted on the second obverse surface;
a first sheet with light-passing and insulating properties interposed between the light-receiving element and the light-emitting element in the thickness direction; and
a resin part covering the light-receiving element, the light-emitting element and the first sheet, wherein
the first sheet includes a first surface facing the first side in the thickness direction and a second surface facing away from the first surface,
the resin part includes a transparent resin and a sealing resin, the transparent resin covering at least a portion of each of the light-receiving element and the light-emitting element and a portion of the first sheet, the sealing resin covering the transparent resin and a portion of the first sheet,
the first sheet is formed with one or more openings each penetrating from the first surface to the second surface, and
each of the openings is filled with the resin part.

15. The semiconductor device according to claim 14, wherein each of the openings is filled with the transparent resin.

16. The semiconductor device according to claim 15, further comprising a wire bonded to the light-receiving element or the light-emitting element,
wherein as viewed in the thickness direction, a dimension of each of the openings in a direction in which the wire extends is in a range of 0.5 to 2 times a diameter of the wire.
